(19) United States
(12) Patent Application Publication
(10) Pub. No.: US 2026/0123080 A1
(43) Pub. Date: Apr. 30, 2026

(54) PIXEL ARRAY STRUCTURE INCLUDING A PLURALITY OF PHOTO DETECTING ELEMENTS AND ELECTRONIC DEVICE INCLUDING THE SAME

(71) Applicant: SK hynix Inc., Icheon-si (KR)

(72) Inventor: Jong Chae KIM, Icheon-si (KR)

(21) Appl. No.: 19/041,336

(22) Filed: Jan. 30, 2025

(30) Foreign Application Priority Data
Oct. 28, 2024 (KR) 10-2024-0148397

(51) Int. Cl. H10F 39/00

(52) U.S. Cl. CPC H10F 39/807; H10F 39/8053; H10F 39/8063; H10F 39/811

(57) ABSTRACT

A pixel array structure may include a plurality of photo detecting elements disposed in a substrate, an interconnection layer, and a pixel isolation layer. The pixel isolation layer may partition the substrate and the interconnection layer such that the plurality of photo detecting elements may be isolated from each other. The transparency (and/or color) of the pixel isolation layer has a first state before a voltage that is higher than or equal to a threshold voltage is applied to the pixel isolation layer, and when voltage that is higher than or equal to the threshold voltage is applied to the pixel isolation layer, the transparency (and/or color) of the pixel isolation layer may transition from the first state to a second state.

### CROSS-REFERENCES TO RELATED APPLICATION

This patent document claims the priority and benefits of Korean application number 10-2024-0148397, filed on Oct. 28, 2024, which is incorporated herein by reference in its entirety.

### TECHNICAL FIELD

The technology and implementations disclosed in this patent document relate to electronic devices and, more particularly, to a pixel array structure of an image sensing device.

### BACKGROUND

Electronic devices, such as LiDAR (Light Detection and Ranging) devices, may utilize a photo-detecting element and function as remote sensors configured to measure the position coordinates of a reflector using light. Examples of LiDAR devices may include a single photon avalanche diode (SPAD) which is capable of detecting a single photon based on an avalanche phenomenon to generate a significantly large current from a small amount of incident light.

### SUMMARY

The disclosed technology can be implemented in some example embodiments to provide a pixel array structure capable of preventing a crosstalk between neighboring pixels.

The disclosed technology can also be implemented in some example embodiments to provide an electronic device including the above-mentioned pixel array structure.

In some embodiments, a pixel array structure may include a plurality of photo detecting elements supported by a substrate, e.g., disposed or formed in the substrate, an interconnection layer, and a pixel isolation layer. The substrate may include a first surface and a second surface that is opposite to the first surface or faces the first surface. The interconnection layer is formed over the first surface of the substrate. The interconnection layer may include a plurality of interconnects connected to the plurality of photo detecting elements. In an implementation, the interconnection layer may further include at least one insulating layer configured to insulate the plurality of interconnects. The pixel isolation layer extends from the substrate to the interconnection layer and is configured to isolate the plurality of photo detecting elements from each other. In some implementations, the pixel isolation layer exhibits a light transmission characteristic that varies depending on a voltage applied to the pixel isolation layer. In some implementations, the light transmission characteristic includes at least one of transparency or color of the pixel isolation layer. In other words, at least one of transparency and color of the pixel isolation layer changes depending on a voltage applied to the pixel isolation layer.

In example embodiments, the pixel isolation layer may include a metal oxide including metal. The metal include at least one of tungsten (W), iridium (Ir), molybdenum (Mo), nickel (Ni) and vanadium (V). The pixel isolation layer may include an organic material including viologens or quinones. The pixel isolation layer may include an electrochemical material. The electrochemical material may include a conductive polymer including at least one of polythiophene, polyaniline (PANI), or polypyrrole.

In example embodiments, the pixel isolation layer may include a binning pixel isolation layer and a unit pixel isolation layer. The binning pixel isolation layer is disposed on a periphery of at least two adjacent photo detecting elements among the plurality of photo detecting elements. The at least two adjacent photo detecting elements operate as a binning pixel. The unit pixel isolation layer defines each of the photo detecting elements except for the binning pixel. When the voltage above the threshold voltage is applied to the binning pixel isolation layer and the unit pixel isolation layer, the binning pixel isolation layer and the unit pixel isolation layer transition from a first state to a second state different from the first state.

In some embodiments, an electronic device may include a pixel array structure and a logic circuit structure.

In example embodiments, the pixel array structure may include a substrate and a plurality of photo detecting elements supported by the substrate, an interconnection layer including a plurality of interconnects positioned on a front side of the substrate, and a pixel isolation layer including a plurality of isolation regions extending from a back side of the substrate to a front side of the interconnection layer for individually isolating the plurality of photo detecting elements. The pixel isolation layer may include a selectively opaque material, such as an electrochromic material.

In example embodiments, the logic circuit structure may include a plurality of control logic circuits configured to provide a plurality of operating voltages to the plurality of interconnect layers in the interconnection layer.

In example embodiments, a transparency and a color of the pixel isolation layer may transition from a first state to a second state, based on a threshold voltage.

For example, when a voltage lower than a threshold voltage is applied to the pixel isolation layer, the pixel isolation layer has the first state. When a voltage higher than or equal to the threshold voltage is applied to the pixel isolation layer, the pixel isolation layer transitions to the second state. The second state has a lower transparency than the first state, or the second state has a darker color than the first state.

In some embodiments, the pixel isolation layer may be formed through the substrate and the interconnection layer. The pixel isolation layer may include the material discolored by a voltage. As the pixel isolation layer formed to penetrate the pixel array structure may be selectively discolored by the voltage, an optical crosstalk between the photo detecting elements as well as between the interconnection layers corresponding to the photo detecting elements may be prevented. In particular, in a case of a Lidar device including a SPAD configured to generate a pixel current with a single photon, abnormal pixel currents in off-pixels and noises caused by an optical crosstalk generated in the interconnection layer may also be prevented.

Furthermore, since the transparency of the pixel isolation layer varies depending on the voltage applied to the pixel isolation layer, the binning pixel of various sizes can be formed within the pixel array structure.

### BRIEF DESCRIPTION OF THE DRAWINGS

The above and another aspects, features and advantages of the subject matter of the present disclosure will be more easily understood from the following detailed description taken in conjunction with the accompanying drawings.

FIG. 1 is a perspective view illustrating a pixel array structure of an electronic device based on example embodiments.

FIGS. 2A and 2B are perspective views illustrating a unit pixel based on example embodiments.

FIG. 3 is a plan view illustrating a photo detecting element based on example embodiments.

FIG. 4 is a cross-sectional view taken along line a A-A′ in FIG. 3.

FIGS. 5A to 5C are cross-sectional views illustrating a method of manufacturing a pixel isolation layer based on example embodiments.

FIGS. 6A to 6C are cross-sectional views illustrating a method of manufacturing a pixel isolation layer based on example embodiments.

FIGS. 7A and 7B are cross-sectional views illustrating operations of a pixel isolation layer based on example embodiments.

FIG. 8 is a cross-sectional view illustrating an electronic device including a pixel isolation layer based on example embodiments.

FIG. 9 is a perspective view illustrating a pixel array structure including pixels of various sizes based on example embodiment.

FIG. 10 is a cross-sectional view taken along line b-b′ in FIG. 9.

FIGS. 11A and 11B are perspective views illustrating a pixel array structure of a pixel-scalable electronic device based on example embodiments.

FIGS. 12A and 12B are perspective views illustrating a pixel array structure of an electronic device capable of changing sizes of binning pixels based on example embodiments.

### DETAILED DESCRIPTION

In the devices disclosed herein, a photo detecting element, such as a SPAD, may be integrated into a pixel region of a substrate partitioned by a pixel isolation layer. However, defects may be generated in the substrate during the process of forming the pixel isolation layer. These defects may cause noise in the SPAD, thereby degrading image quality.

Furthermore, when light with long wavelengths, such as infrared light, is irradiated onto a receiving surface of the SPAD, the infrared light may penetrate to an insulating layer located on the substrate. Since the insulating layer does not have boundaries between the pixel regions, an optical crosstalk may occur between neighboring pixels.

The disclosed technology can be implemented in some embodiments to provide a pixel isolation layer in a pixel array structure that may prevent crosstalk between a plurality of photo detecting elements.

In some embodiments, the pixel isolation layer may extend into the substrate as well as into an interconnection layer comprising an insulating layer to penetrate the pixel array structure. Furthermore, the pixel isolation layer based on some embodiments selectively changes to an opaque state when a voltage (or current) above a threshold voltage is applied to the pixel isolation layer. Accordingly, a crosstalk between neighboring pixels may be prevented by the pixel isolation layers extending to the interconnection layer, even if light with a long wavelength light is incident on the pixel array structure.

Furthermore, the pixel isolation layers based on some embodiments may be conductive. Accordingly, photons remaining in the non-selected pixels may be captured, preventing abnormal behavior of the remaining photons.

In some embodiments, a first face or first surface may be a front side, and a second face or second surface may be a back side. A side surface or a sidewall may refer to a surface located on the left or right surfaces of the drawing.

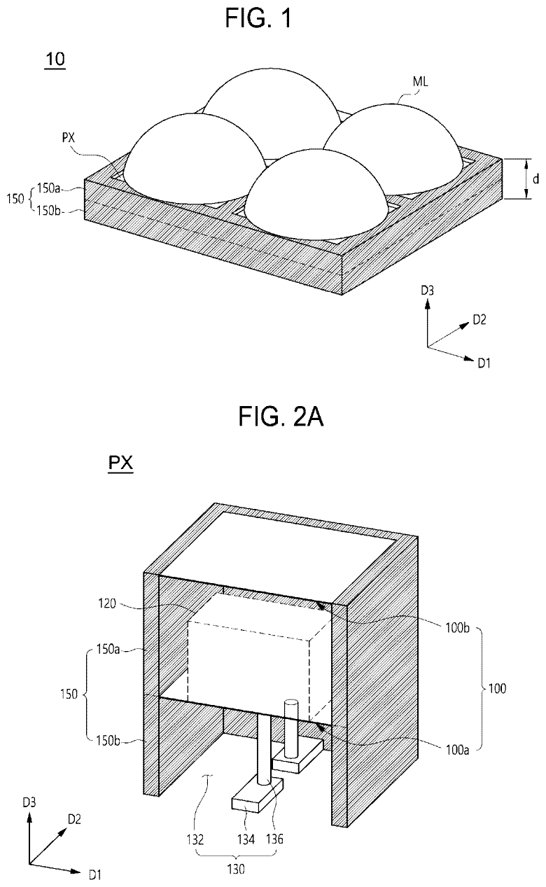

FIG. 1 is a perspective view illustrating a pixel array structure of an electronic device based on example embodiments.

Referring to FIG. 1, a pixel array structure 10 of an electronic device may include a plurality of unit pixels PX. The plurality of unit pixels may be defined by a pixel isolation layer 150. For example, the plurality of unit pixels PX may be arranged in a matrix form along a first direction D1 and a second direction D2 perpendicular to the first direction D1.

In example embodiments, each unit pixel PX may include, for example, a photo detecting element configured to receive incident light and converts the incident light into photons.

Alternatively, each unit pixel PX may include a photo detecting element configured to: receive the light reflected from an object (not shown); convert the reflected light into the photons; and generate a pixel signal based on the amount of the photons. The photo detecting element utilizing the light reflected from the object may include a single photon avalanche diode (SPAD) based on a direct time of flight (ToF) method. The direct ToF SPAD may detect a distance between the object and the electronic device by measuring a time for an irradiated pulsed laser signal to reflect back from the object.

The pixel isolation layer 150 configured to isolate the pixels PX may extend from a back side toward a front side of the pixel array structure 10. For example, the pixel isolation layer 150 based on example embodiments may have a thickness substantially equal to a thickness d of the pixel array structure 10.

In example embodiments, the pixel array structure 10 may include a substrate (not shown), a photo detecting element (not shown) supported by the substrate, and an interconnection layer (not shown) formed over the substrate. For example, the substrate may include the photo detecting element. Further, the pixel isolation layer 150 may include a first pixel isolation layer 150a formed in the substrate, and a second pixel isolation layer 150b formed in the interconnection layer. The second pixel isolation layer 150b may extend from an upper surface of the first pixel isolation layer 150a to an upper surface of the interconnection layer.

In addition, the pixel isolation layer 150 based on example embodiments may include an electrochromic material that may reversibly change its transparency or color depending on a magnitude of an applied voltage and/or a direction of an electric field. For example, the electrochromic material may include a metal oxide including at least one of tungsten (W), iridium (Ir), molybdenum (Mo), nickel (Ni), or vanadium (V). Further, the electrochromic material may include an organic material such as viologens or quinone. Furthermore, the electrochromic material may include conductive polymers such as polythiophene, polyaniline (PANI) and polypyrrole. In some implementations, the conductive polymer may change their molecular arrangement (or structure) upon applying a low voltage, which may cause the conductive polymeric materials to change a color. Therefore, the pixel isolation layer 150 may be formed of the electrochromic material with the conductive polymer, an opaque pixel isolation layer 150 may be formed by applying a low voltage.

When a voltage lower than a threshold voltage, or no voltage is applied to the pixel isolation layer 150, the pixel isolation layer 150 may have a first state. For example, the first state may be a transparent state. Alternately, the first state of the pixel isolation layer 150 may include a first color.

On the other hand, when a voltage higher than or equal to the threshold voltage is applied to the pixel isolation layer 150, the pixel isolation layer 150 may have a second state different from the first state. For example, the second state may be a lower transparent state than the first state. Alternately, the second state may include a second color being different from the first color, such as a darker color. In example embodiments, the first state may be transparent state, and the second state may be a state having a color including black. Accordingly, an optical crosstalk between the photo detecting elements formed in the substrate, as well as an optical crosstalk between the interconnection layers, may be effectively reduced or prevented.

The pixel isolation layer 150 including the electrochromic material may be selectively conductive. Accordingly, the pixel isolation layer 150 may capture photons that remain in the unselected pixels, thereby preventing an abnormal current generation.

Further, the pixel array structure 10 may include a plurality of micro-lenses ML. For example, the micro-lenses ML may be formed to overlap at least one pixel PX. In example embodiments, the micro-lenses ML may be disposed over the back side of the substrate, but are not limited thereto.

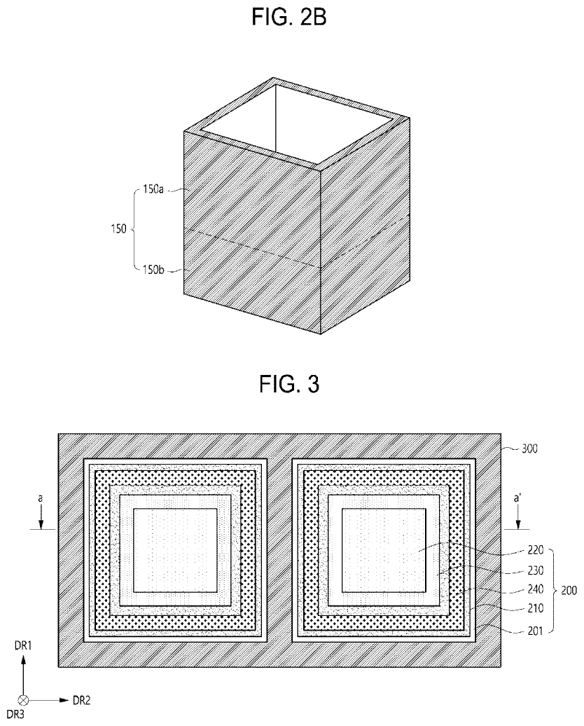

FIGS. 2A and 2B are perspective views illustrating a unit pixel based on example embodiments.

Referring to FIG. 2A, a unit pixel PX may include a substrate 100, a photo detecting element 120, an interconnection layer 130 and a pixel isolation layer 150.

For example, the substrate 100 may include a semiconductor material such as Si, Ge, or SiGe. The substrate 100 may include a first conductive type impurities or a second conductive type impurities. The second conductive type may be the opposite conductive type to the first conductive type. For example, the first conductive impurities may be a p-type impurities, and the second conductive impurities may be an n-type impurities. Further, the substrate 100 may include a first surface 100a and a second surface 100b that are opposite to each other. For example, the first surface 100a may correspond to a front side of the substrate 100, and the second surface 100b may correspond to a back side of the substrate 100.

The photo detecting element 120 is supported by the substrate 100. In this example, the photo detecting element 120 may be formed in in the substrate 100, e.g., in an area adjacent to the first surface 100a of the substrate 100, but is not limited thereto. For example, the photo detecting element 120 may include an SPAD or an avalanche photo diode (APD). The detailed structure of the photo detecting element 120 will be described later.

The interconnection layer 130 may be formed over a first portion of the first surface 100a of the substrate 100 in which the photo detecting element 120 may be formed. The interconnection layer 130 may include at least one insulating layer 132, a plurality of horizontal interconnects 134 and a plurality of vertical interconnects 136. For example, the insulating layer 132 may electrically isolate the plurality of horizontal interconnect 134 from the photo detecting element 120. The plurality of horizontal interconnects 134 may extend substantially parallel to the first surface 100a of the substrate 100. A plurality of vertical interconnects 136 may electrically connect the plurality of horizontal interconnects 134 to the photo detecting element 120. For example, the vertical interconnect 136 may extend in a direction perpendicular to the first surface 100a of the substrate 100. The plurality of horizontal interconnects 134 and the plurality of vertical interconnects 136, which receive different voltages, may be electrically isolated by the insulating layer 132. FIG. 2A illustrates one example of the interconnection layer 130, but is not limited thereto and may be configured in various ways.

In other words, the pixel isolation layer 150 may be formed to surround sidewalls of the unit pixels PX. The sidewalls of the unit pixels PX may include the substrate 100 and the interconnection layer 130. Also, although not shown, the pixel isolation layer 150 may include an insulating liner (not shown) configured to insulate the substrate 100 and the interconnection layer 130 corresponding to the sidewalls of the unit pixels PX.

While FIG. 2A illustrates the pixel isolation layer 150 with one opened surface for ease of description, the actual pixel isolation layer 150 may be formed as a framed column structure to enclose the entire sidewall surface of an area intended for the unit pixel PX, as shown in FIG. 2B.

A pixel isolation layer may be formed in a structure of a deep trench only in the substrate 100 in which the photo detecting elements may be embedded. Therefore, an optical crosstalk between the photo detecting elements formed in the substrate 100 may be easily prevented. However, when incident light with a long wavelength is irradiated, or when noise is generated due to abnormal light emission in the interconnection layer 130 after the operation of the photo detecting elements, optical crosstalk may still occur within the interconnection layer 130.

On the other hand, the pixel isolation layer 150 based on example embodiments may be configured to extend through the substrate 100 and into the interconnection layer 130 located on the front surface of the substrate 100, which may address the optical crosstalk issues that may occur in the substrate 100 as well as in the interconnection layer 130.

In example embodiments, the first pixel isolation layer 150a located in the substrate 100 of the pixel isolation layers 150 may prevent an optical crosstalk between neighboring photo detecting elements 120. Further, the second pixel isolation layer 150b located in the interconnection layer 130 may prevent noises migration between the interconnection layers 130 partitioned by unit pixels PX.

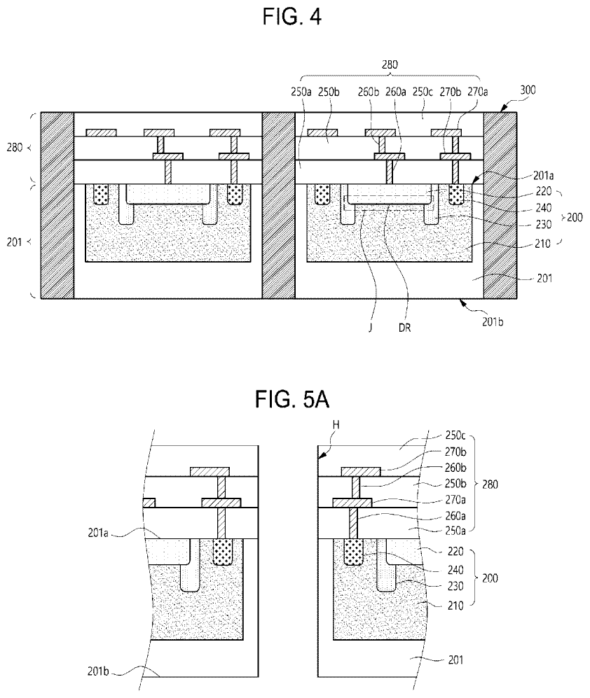

FIG. 3 is a plan view illustrating a photo detecting element based on example embodiments, and FIG. 4 is a cross-sectional view taken along a line A-A′ in FIG. 3.

Referring to FIGS. 3 and 4, a photo detecting element 200 may be an SPAD having at least one PN junction J. In some implementations, the SPAD may detect a single photon reflected from an object and generate a current pulse corresponding to the detected single photon. For example, when a reverse bias voltage higher than a breakdown voltage of the SPAD is applied between a cathode and an anode, e.g., in the Geiger mode, an incident single photon may cause an avalanche breakdown, and the current pulse may be generated. More specifically, when the reverse bias voltage above the breakdown voltage is applied to the cathode and anode of the SPAD, an electric field may be generated between the cathode and anode by the reverse bias voltage. At this point, the photons incident on the Geiger mode may be converted into electrons by the SPAD and may be moved to generate electron-hole pairs, resulting in impact ionization. A measurable current pulse may be generated by the large number of carriers generated by the impact ionization phenomenon. The avalanche breakdown may cause a depletion region (DR) in the SPAD, e.g., at the p-n junction (J), the junction surface of the cathode and anode. Note that the absolute value of the reverse bias voltage may be greater than the absolute value of the breakdown voltage.

The photo detecting element 200 may be formed in a substrate 201. For example, the substrate 201 may include a bulk single crystal silicon wafer, a silicon on insulator (SOI) wafer, a compound semiconductor wafer such as Si—Ge, a wafer on which a silicon epitaxial layer has been grown, and the like. For example, the substrate 201 may include, but is not limited to, first conductive type impurities, such as the p-type impurities.

The photo detecting element 200 may include a first impurities region 210 and a second impurities region 220 that generate at least one PN junction.

The first impurities region 210 may be formed in the substrate 201. For example, the first impurities region 210 may be a well. The first impurities region 210 may include a second conductive type, such as n-type impurities. For example, the first impurities region 210 may be used as a cathode for the SPAD.

The second impurities region 220 may be formed in the first impurities region 210. The second impurities region 220 may be formed adjacent to the first surface 201a of the substrate 201. The second impurities region 220 may include impurities of a first conductive type opposite to the first impurities region 210, such as p-type impurities. The second impurities region 220 may have a shallower depth than the first impurities region 210, and may have a higher doping concentration than the doping concentration of the first impurities region 210. Accordingly, the PN junction J may be generated between the second impurities region 220 and the first impurities region 210. For example, the second impurities region 220 may be used as an anode of the SPAD.

The photo detecting element 200 may further include a guard ring 230 and a contact region 240.

The guarding ring 230 may be formed in the first impurities region 210. The guard ring 230 may be in contact with a surface of the second impurities region 220. For example, a junction depth of the guarding ring 230 may be greater than a junction depth of the second impurities region 220 and less than a junction depth of the first impurities region 210. Further, the guarding ring 230 may have the same conductivity as the second impurities region 220, and a doping concentration of the guarding ring 230 may be lower than a doping concentration of the second impurities region 220 and higher than a doping concentration of the first impurities region 210. The guarding ring 230 may be formed to surround an edge of the second impurities region 220, thereby preventing an electric field from being concentrated at an edge portion of the second impurities region 220. Accordingly, a premature breakdown of the SPAD may be prevented. In example embodiments, the guarding ring 230 may be described as an impurity region, but without limitation, the guarding ring 230 may be formed in a structure of a device isolation layer.

The contact region 240 may be formed to include the second conductive impurities in the first impurities region 210. A doping concentration of the contact region 240 may be higher than the doping concentration of the first impurities region 210. The contact region 240 may be in contact with a conductive interconnect (e.g., 260a) for transferring a cathode voltage. For example, the contact region 240 may be formed in the first impurities region 210 adjacent to the guarding ring 230, but is not limited thereto. The contact region 240 may have a similar junction depth to the second impurities region 220, but is not limited thereto.

Furthermore, although not shown in the drawings, the photo detecting element 200 may further include a buffer region which formed under the contact region 240. The buffer region may have the same conductivity as the first impurities region 210 and the contact region 240, but may be greater than the doping concentration of the first impurities region 210 and less than the doping concentration of the contact region 240.

While the SPAD introduced in FIG. 3 illustrates the structure with the single p-n junction J, the SPAD may include multiple PN junctions.

Also, while the SPAD in FIG. 3 illustrates a rectangular planar structure within square pixels, the SPAD may be fabricated with circular or polygonal planar structures.

Referring to FIG. 4., an interconnection layer 280 may be formed on the first surface 201a of the substrate 201 on which the photo detecting element 200 may be formed. The interconnection layer 280 may include multilayer interconnect structures 260a-260b and 270a-270b, and multi insulation layers 250a-250c for connecting the photo detecting element 200 with a control logic circuit (not shown).

For example, the interconnection layer 280 may be formed as follows.

First, a first insulating layer 250a may be formed on the first surface 201a of the substrate 201. First contact holes (not shown) may be formed in the first insulating layer 250a such that a selected portion of the second impurities region 230 and a selected portion of the contact region 240 may be exposed, respectively. A conductive material may be formed in the first contact holes to form first vertical interconnects 260a. The first vertical interconnects 260a may also be referred to as contacts or contact plugs. First horizontal interconnects 270a may be formed on the first insulating layer 250a. The first horizontal interconnects 270a may be in contact with the first vertical interconnect lines 260a, respectively.

The second insulating layer 250b may be formed on the first insulating layer 250a on which the first horizontal interconnects 270a may be formed. The second insulating layer 250b may be etched such that a predetermined portion of the first horizontal interconnect 270a may be exposed to form second contact holes (not shown) in the second insulating layer 250b. A conductive material may be formed in the second contact holes to form second vertical interconnects 260b. Second horizontal interconnects 270b may be formed on the second insulating layer 250b. The second horizontal interconnects 270b may be connected with the second vertical interconnects 260b.

The third insulating layer 250c may be formed on the second insulating layer 250b. The third insulating layer 250c may be utilized as a passivation layer. The third insulating layer 250c may include vertical interconnects and/or horizontal interconnects as described above.

Thus, an interconnection layer 280 may be formed on the first surface 201a of the substrate 201. The interconnection layer 280 shown in FIG. 4 is only one example, and the interconnection layer 280 may be formed by a greater number of insulating layers, vertical interconnects, and horizontal interconnects.

The pixel isolation layer 300 may be formed to surround each of the photo detecting elements 200 to electrically and optically isolate between the photo detecting elements 200. The pixel isolation layer 300 may extend from the second surface 201b of the substrate 201 to an upper surface of the interconnection layer 280. In some cases, a first portion of the pixel isolation layer 300 may extend to an upper region of the interconnection layer 280. The first portion of the pixel isolation layer 300 may be electrically connected to external electrode terminals (not shown) via vertical and horizontal interconnects. Furthermore, the pixel isolation layer 300 based on example embodiments may include a material that optionally changes its transparency and color whenever a threshold voltage may be applied. For example, the pixel isolation layer 300 may include an electrochromic material. The pixel isolation layer 300 may be conductive, with the transparency and/or color changing whenever a voltage higher than or equal to the threshold voltage may be applied.

As the pixel isolation layer 300 may be conductive, an outer sidewall of the pixel isolation layer 300 may be covered by an insulating liner (not shown). Accordingly, the pixel isolation layer 300 may be electrically isolated between the substrate 201 and the pixel isolation layer 300 and between the interconnection layer 280 and the pixel isolation layer 300 by the insulating liner.

Furthermore, the pixel isolation layer 300 that exhibits conductivity may be used as an electrode. Accordingly, residual charges in non-selected pixels may be captured, thereby blocking the abnormal current generation and the noise migration.

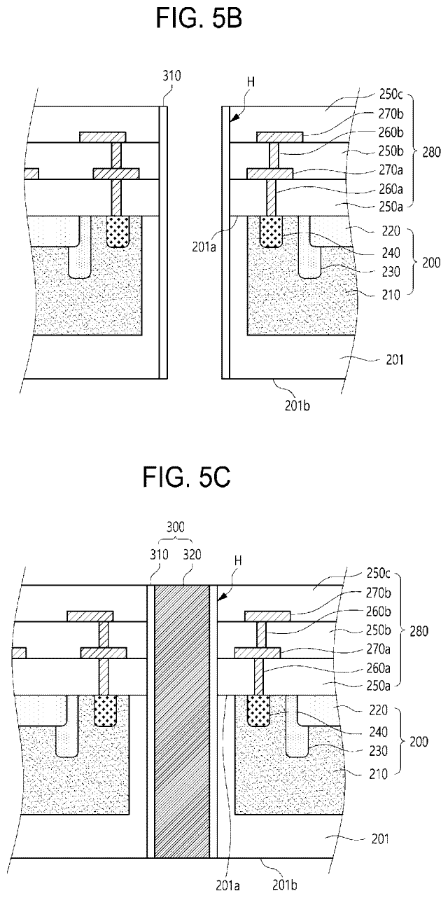

FIGS. 5A through 5C are cross-sectional views illustrating a method of manufacturing a pixel isolation layer based on example embodiments.

Referring to FIG. 5A, an interconnection layer 280 may be formed over the substrate 201 on which the photo detecting elements 200 are formed. Then, a trench H may be formed through the interconnection layer 280 and the substrate 201 to isolate the photo detecting elements 200. For example, the trench H may be formed by at least one anisotropic etch process. The anisotropic etching process may use various etching processes, for example, a trench forming method to form deep trench isolation (DTI) or a deep reactive ion etching (DRIE) method to form through silicon via (TSV).

Referring to FIG. 5B, an insulating liner 310 may be formed on a sidewall of the trench H. The insulating liner 310 may include an insulating layer, such as, for example, a silicon oxide layer or a silicon nitride layer. For example, the insulating liner 310 may be formed by anisotropic etching, such as spacer etching, after depositing the insulating layer.

Referring to FIG. 5C, the electrochromic layer 320 may be formed in the trench H. For example, various application methods may be utilized to ensure that the electrochromic material 320 may be fully formed in the trench H without voids. The electrochromic material 320 may also be formed over the interconnection layer 280 to fill the trench H. Alternatively, with the substrate 201 being flipped, the electrochromic layer 320 may be formed on the second surface 201b of the substrate 201 to fill the trench H. The electrochromic material 320 may be planarized so that the upper surface of the interconnection layer 280 and the second surface 201b of the substrate 201 may be substantially coplanar with each other to form the pixel isolation layer 300.

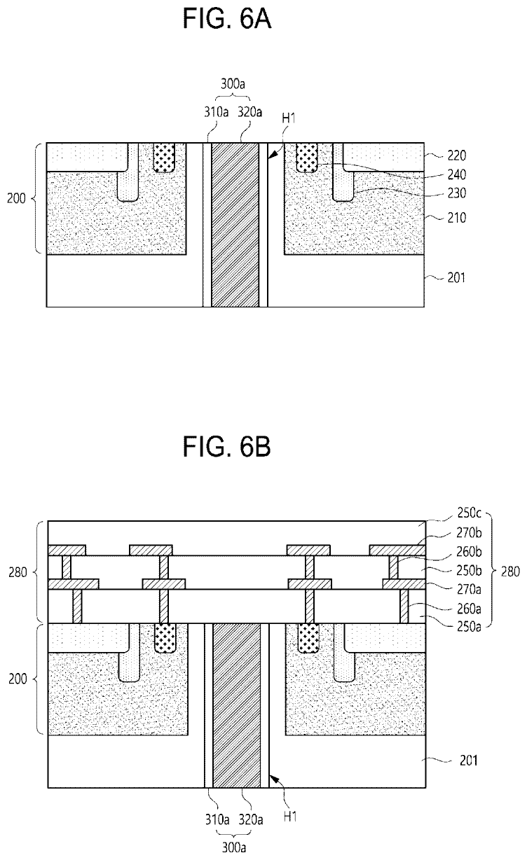

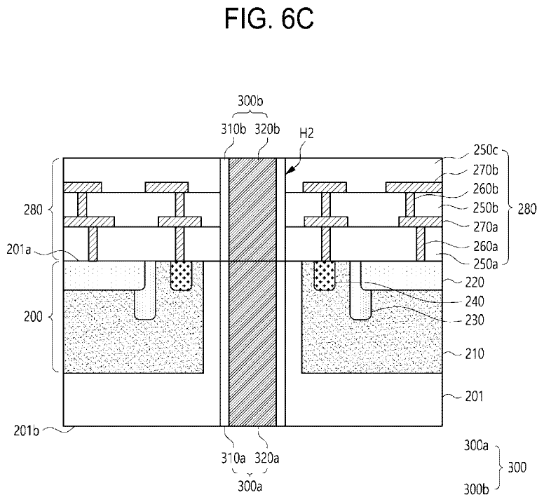

FIGS. 6A to 6C are cross-sectional views illustrating a method of manufacturing a pixel isolation layer based on example embodiments.

Referring to FIG. 6A, after the plurality of photo detecting elements 200 are formed in the substrate 201, and before the interconnection layer 280 is formed, a selected portion of the substrate 201 may be etched to form a first trench H1. For example, the first trench H1 may be located in the substrate 201 between the photo detecting elements 200.

Thereafter, a first insulating liner 310a may be formed along a sidewall and a bottom surface of the first trench H1. A first electrochromic material 320a may be formed in the first trench H1 with the first insulating liner 310a to form a lower pixel isolation layer 300a.

Next, referring to FIG. 6B, an interconnection layer 280 including a plurality of insulating layers 250a-250c, a plurality of vertical interconnects 260a-260b and a plurality of horizontal interconnects 270a-270b may be formed on the substrate 201 on which the photo detecting element 200 and the lower pixel isolation layer 300a may be formed.

Referring to FIG. 6c, a second trench H2 may be formed in the interconnection layer 280 to expose the lower pixel isolation layer 300a. For example, the second trench H2 may be formed in the interconnection layer 280 such that the second trench H2 may have substantially the same shape as the first trench H1. However, without limitation, the second trench H2 may be formed to have a different width than the first trench H1.

Thereafter, a second insulating liner 310b may be formed on a sidewall of the second trench H2. The second insulating liner 310b may include the same material as the first insulating liner 310a. However, without limitation, various insulating materials may be utilized as the second insulating liner 310b.

A second electrochromic layer 320b may be formed in the second trench H2. The second electrochromic layer 320b may be formed in the second trench H2 such that the first electrochromic layer 320a of the lower pixel isolation layer 300a may be at least partially in contact with the second electrochromic layer 320b. Accordingly, when a voltage is applied through the upper surface of the interconnection layer 280 or the second surface 201b of the substrate 201, the first and second electrochromic layers 310a and 310b may be conducted and simultaneously discolored. For example, the second electrochromic layer 320b may be the same material as the first electrochromic layer 320a. However, without limitation, any material having variable transparency and conductivity properties within a voltage range similar to the first electrochromic layer 320a may be utilized as the second electrochromic layer 320b. Thus, an upper pixel isolation layer 300b may be formed in the interconnection layer 280 in contact with the lower pixel isolation layer 300a. The upper pixel isolation layer 300b may partition the interconnection layer 280 on a pixel-by-pixel basis, thereby preventing the optical crosstalk in the interconnection layer 280.

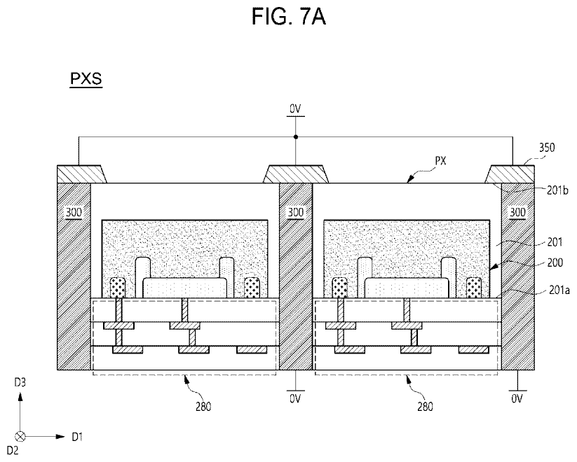

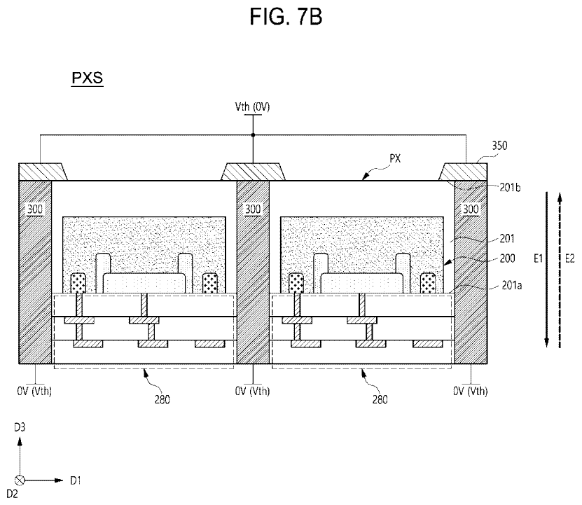

FIGS. 7A and 7B are cross-sectional views illustrating operations for a pixel isolation layer based on example embodiments.

Referring to FIGS. 7A and 7B, a pixel array structure PXS may include a substrate 201 including a plurality of photo detecting elements 200, an interconnection layer 280 formed on a first surface 201a of the substrate 201, a pixel isolation layer 300 to define a plurality of unit pixels in the substrate 201 and interconnection layer 280, and a grid pattern 350. The structure of the substrate 200 including the photo detecting elements and the interconnection layer 280 may be the same as the examples discussed above.

In example embodiments, the pixel array structure PXS may be irradiated by a light through a second surface 201b of the substrate 201. Accordingly, the pixel array structure PXS may be flipped such that the second surface 201b of the substrate 201 may face upward.

Furthermore, the grid pattern 350 may be positioned over the second surface 201b of the substrate 201. Although not shown, color filters and micro-lenses may further be formed over the grid pattern 350.

The grid pattern 350 may be provided to prevent a color mixing of the color filter (not shown). In example embodiments, the grid pattern 350 may include a conductive material and may be electrically connected to a first portion of the pixel isolation layer 300 exposed through the second surface 201b of the substrate 201.

In example embodiments, the grid pattern 350 may be electrically connected to a threshold voltage terminal or ground voltage terminal that may discolor the pixel isolation layer 300 by isolate interconnect (not shown).

In addition, the other end of the pixel isolation layer 300 exposed by the interconnection layer 280 may also be electrically connected to the ground voltage terminal or the threshold voltage terminal by various conductive elements (not shown).

In example embodiments, the threshold voltage terminal may be an isolate voltage terminal or may be one of internal voltage lines for driving the photo detecting element 200. The ground voltage terminal may also be one of the lines configured to carry a ground voltage.

For illustration purposes, an example where voltage is applied through one end and the other end of the pixel isolation layer 300 is illustrated, but the other end of the pixel isolation layer 300 may also be in contact with one of the horizontal or vertical interconnects of the interconnection layer 280.

For example, as shown in FIG. 7A, when 0 volt is applied to the grid pattern 350 and the other end of the pixel isolation layer 300, respectively, e.g., when no voltage is applied to the pixel isolation layer 300, the pixel isolation layer 300 may maintain the transparency and/or color of the first state.

On the other hand, as shown in FIG. 7B, when a voltage higher than or equal to the threshold voltage Vth is applied through the grid pattern 350 or the other end of the pixel isolation layer 300, the transparency and/or color of the electrochromic material layer including the pixel isolation layer 300 may be changed into a second state by the level of the threshold voltage Vth and/or the direction of the electric fields E1 and E2 based on the threshold voltage Vth.

For example, applying the threshold voltage Vth to the grid pattern 350 and a relatively low voltage, such as a ground voltage of 0V, to the other end of the pixel isolation layer 300 may generate a first electric field E1 directed from the second surface 201b of the substrate 201 to the interconnection layer 280. Alternatively, applying a ground voltage of 0V to the grid pattern 350 and the threshold voltage Vth to the other end of the pixel isolation layer 300 may generate a second electric field E2 directed from the interconnection layer 280 toward the grid pattern 350.

Furthermore, the transparency and color of the pixel isolation layer 300 may be changed based on the direction of the first electric field E1 or second electric field E2. Accordingly, a unit pixel PX including a single photo detecting element 200 may be completely partitioned from the second surface 201b of the substrate 201 to the surface of the interconnection layer 280.

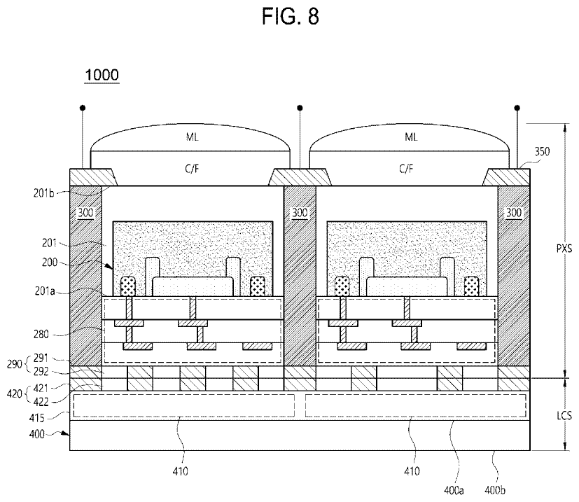

FIG. 8 is a cross-sectional view illustrating an electronic device including a pixel isolation layer based on example embodiments.

Referring to FIG. 8, an electronic device 1000 may include a pixel array structure PXS and a logic circuit structure LCS.

The pixel array structure PXS may include a substrate 201 including a plurality of photo detecting elements 200, an interconnection layer 280 formed on a first surface 201a of the substrate 201, and a pixel isolation layer 300 configured to penetrate the substrate 201 and the interconnection layer 280 to individually define the photo detecting elements 200, as described above.

In addition, the pixel array structure PXS may further include a first bonding layer 290 formed on the surface of the interconnection layer 280 and the pixel isolation layer 300. The first bonding layer 290 may include a plurality of first bonding pads 291 and a first bonding insulation layer 292 configured to insulate between the plurality of first bonding pads 291. In some implementations, each of the first bonding pads 291 may be electrically coupled to various interconnects of the interconnection layer 280. For example, the first bonding pads 291 may include a metal material such as copper. The first bonding insulating layer 292 may include at least one of a silicon oxide layer and a silicon nitride layer.

The logic circuit structure LCS may include a logic substrate 400 having a first surface 400a and a second surface 400b. A circuit layer 415 including a plurality of control logic circuits 410 may be formed on the first surface 400a of the logic substrate 400. For example, the control logic circuits 410 may further include a quenching circuit (not shown), a switching circuit (not shown) and various types of voltage generation circuits (not shown), as well as an image processing circuit (not shown). In addition, the circuit layer 415 may further include connecting interconnects (not shown) configured to electrically connect the control logic circuits 410 with insulating layers (not shown) for insulating between the connecting interconnects.

A second bonding layer 420 may be formed over the circuit layer 415. The second bonding layer 420 may include a plurality of second bonding pads 421 and a second bonding insulating layer 422 configured to insulate the plurality of second bonding pads 421.

The second bonding pads 421 may be electrically coupled to interconnect layers (not shown) of the control logic circuits 410.

The pixel array structure PXS may be stacked on the logic circuit structure LCS, such that the first bonding layer 290 of the pixel array structure PXS and the second bonding layer 420 of the logic circuit structure LCS may face each other. For example, the first bonding layer 290 and the second bonding layer 420 may be hybrid bonded to each other, such that the pixel array structure PXS may be laminated on the logic circuit structure LCS.

The other end of the pixel isolation layer 300 of the pixel array structure PXS may be electrically connected, directly or indirectly, with the first bonding pad 291. Further, the first bonding pad 291 electrically connected to the pixel isolation layer 300 may be hybrid bonded to the second bonding pad 421 to directly or indirectly connect a voltage generation circuit of the control logic circuitry 410 with the second bonding pads 421. Accordingly, the other end of the pixel isolation layer 300 may be provided with the threshold voltage or ground voltage via the control logic circuit 410.

The pixel isolation layer 300 may be selectively discolored by a voltage input through the grid pattern 350 and voltage provided by the control logic circuit 410.

After the pixel array structure PXS and the logic circuit structure LCS may be stacked by the hybrid bonding, a color filter C/F and a micro-lens ML may be formed between the grid patterns 350.

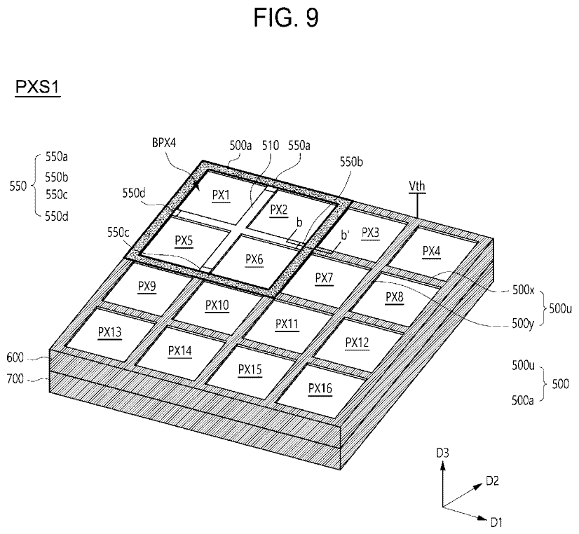

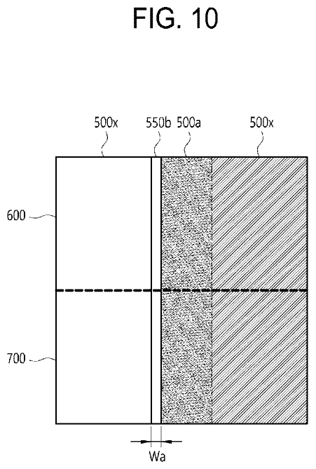

FIG. 9 is a perspective view illustrating a pixel array structure including pixels of various sizes based on example embodiments, and FIG. 10 is a cross-sectional view taken along a line B-B′ of FIG. 9.

Referring to FIG. 9, a pixel array structure PXS1 may include a substrate 600, an interconnection layer 700 and a pixel isolation layer 500.

The substrate 600 may include a plurality of photo detecting elements (not shown) arranged in a matrix form. An area formed by each of the plurality of photo detecting elements may be a unit pixel.

The interconnection layer 700 may be located on a first surface, e.g., a front side of the substrate 600. The interconnection layer 700 may include a plurality of interconnects (not shown) configured to transfer electrical signals to the photo detecting elements and at least one insulating layer (not shown) configured to isolate the interconnects.

The pixel isolation layer 500 may be formed to penetrate the substrate 600 and the interconnection layer 700 to isolate the plurality of photo detecting elements. The pixel isolation layer 500 based on example embodiments may include an electrochromic material configured to change transparency and/or color upon application of a current (or voltage).

In addition, the pixel isolation layer 500 may include a plurality of insulating penetration portions 550 configured to form binning pixels of different sizes. For example, the pixel isolation layer 500 may include a binning pixel isolation layer 500a, an inner pixel isolation region 510, a plurality of insulating penetration portions 550a-550d, and a unit pixel isolation layer 500u.

The binning pixel isolation layer 500a may be disposed at a periphery of at least two adjacent photo detecting elements among the plurality of photo detecting elements. The at least two adjacent photo detecting elements operate as a binning pixel.

The inner pixel isolation region 510 may be positioned between the at least two adjacent photo detecting elements surrounded by the binning pixel isolation layer 510.

The plurality of insulating penetration portions 550 may be positioned at intersections of the binning pixel isolation layer 500a and the inner pixel isolation region 510. The plurality of insulating penetration portions 550 may block a supply of current (or voltage) to the inner pixel isolation region 510. Thus, the inner pixel isolation region 510 may be in an electrically floating state by the plurality of insulating penetration portions 550.

In some implementations, the isolation region located on an outer periphery of the binning pixel, and the isolation region located on the outer periphery of the other unit pixels may receive a threshold voltage.

In this case, a height of the insulating penetration 550 may be equal to or greater than a height of the pixel isolation layer 500 so that the inner pixel isolation region 510 may be completely isolated.

In example embodiments, when planar structures of the unit pixels PX1-PX16 is each rectangular, the unit pixel isolation layer 500u may include a pair of first pixel isolation regions 500x extending parallel to the first direction D1 and a pair of second pixel isolation regions 500y extending parallel to the second direction D2.

In some implementations, the insulation penetration portions 550 configured to form the inner pixel isolation region 510 may be selectively located at the ends of the first pixel isolation region 500x and the second pixel isolation region 500y of the unit pixel to be floated.

In example embodiments, under certain conditions, when the first, second, fifth and sixth pixels PX1, PX2, PX5 and PX6 are binned as a group, the first binning pixel isolation layer 500a located on the periphery of the first, second, fifth and sixth pixels PX1, PX2, PX5 and PX6 (hereinafter, first binning pixel BPX4) may be opaque. The first and second pixel isolation regions 510 located between the first and second pixels PX1 and PX2, between the first and fifth pixels PX1 and PX5, between the second and sixth pixels PX2 and PX6, and between the fifth and sixth pixels PX5 and PX6, that is, the first inner isolation region 510 may be transparent.

To this end, the insulation penetration 550 may include at least first to fourth insulation penetration portions 550a-550d. The first insulation penetration 550a may be located between the first binning pixel isolation layer 500a and an end of the second pixel isolation region 500y, which may be located between the first and second pixels PX1 and PX2. The second insulation penetration 550b may be located between the end of the first pixel isolation region 500x located between the second and sixth pixels PX2 and PX6 and the first binning pixel isolation layer 500a. The third insulation penetration 550c may be located between an end of the second pixel isolation region 500y located between the fifth and sixth pixels PX5 and PX6 and the first binning pixel isolation layer 500a. The fourth insulation penetration 550d may be located between an end of the first pixel isolation region 500x located between the first and fifth pixels PX1 and PX5 and the first binning pixel isolation layer 500a.

As shown in FIG. 10, a width Wa of the insulating penetration portions 550 may be a minimum width capable of electrically isolating the pixel isolation layers 500.

For the operation of the electronic device 1000, a threshold voltage Vth may be applied to the pixel isolation layer 500. Then, all physically connected pixel isolation layers 500u and 500a, except for the first inner pixel isolation region 510 isolated by the insulating penetration portions 550, may become opaquely colored by the threshold voltage Vth. Thus, the pixel array structure PXS1 may be partitioned into a plurality of unit pixels PX3, PX4, PX7, PX8 and PX9-PX16 and a first binning pixel BPX4 into which the 2×2 unit pixels PX1, PX2, PX5 and PX6 may be binned.

While the binning pixels BPX are illustrated as merging four unit pixels PX1, PX2, PX5 and PX6, the size and number of binning pixels BPX may vary.

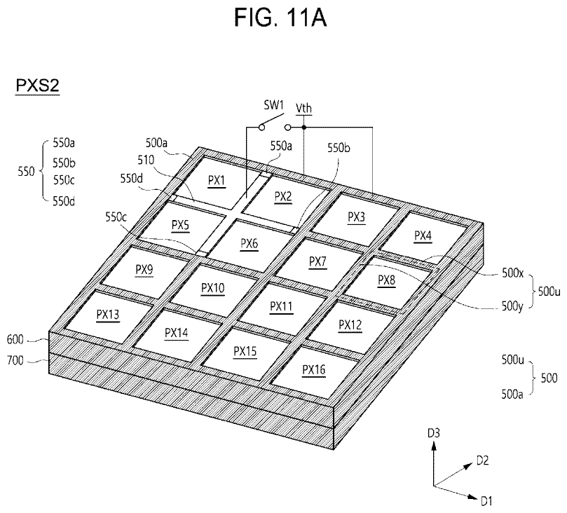

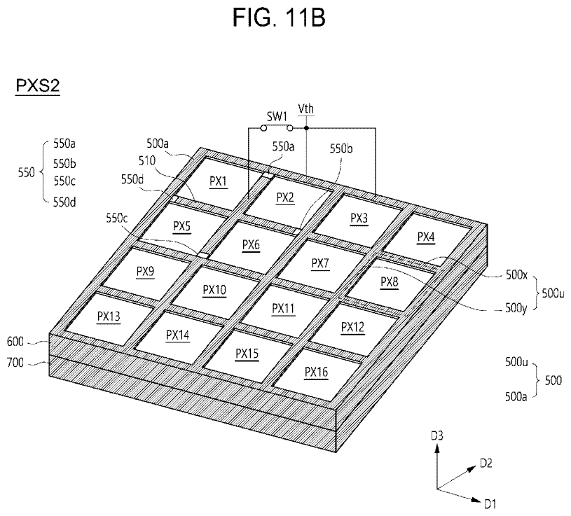

FIGS. 11A and 11B are perspective views illustrating a pixel array structure of a pixel-scalable electronic device based on example embodiments.

Referring to FIG. 11A, an electronic device may include at least one switch SW1 to allow the pixel array structure PXS2 to adjust the size of the pixels.

In example embodiments, the switch SW1 may be connected between the first inner pixel isolation regions 510 located in the first binning pixel isolation layer 500a and the threshold voltage terminal. The switch SW1 may be provided in the pixel array structure PXS1, or may be provided in a logic circuit structure (not shown) in connection with the pixel array structure PXS1.

For example, when a first binning pixel BPX4 with 2×2 unit pixels PX1, PX2, PX5 and PX6 binned in the pixel array structure PXS2 is generated, the switch SW1 may be turned off, as shown in FIG. 11A. Then, a threshold voltage Vth may be applied to the pixel isolation layers 500 except the first inner pixel region 510, causing the first binning pixel isolation layer 500a configured to define the first binning pixel BPX4 and the unit pixel isolation layers 500u defining the other unit pixels to be discolored. Accordingly, the pixel array structure PXS may be defined by the first binning pixel BPX4 with four unit pixels PX1, PX2, PX5 and PX6 merged therewith.

On the other hand, when the first binning pixel BPX4 is not required, the switch SW1 may be turned on, as shown in FIG. 11B. Then, the threshold voltage Vth may be applied to the unit pixel isolation layer 500u, the first binning pixel isolation layer 500a, as well as to the first inner pixel region 510. Accordingly, all pixel isolation layers 500 of the pixel array structure PXS may be discolored and partitioned by unit pixels PX1-PX16. In this case, since the width Wa of the insulation penetration 550 may correspond to the minimum width that may electrically isolate the pixel isolation layers 500, the optical crosstalk phenomenon caused by the insulation penetration 550 may be minimal.

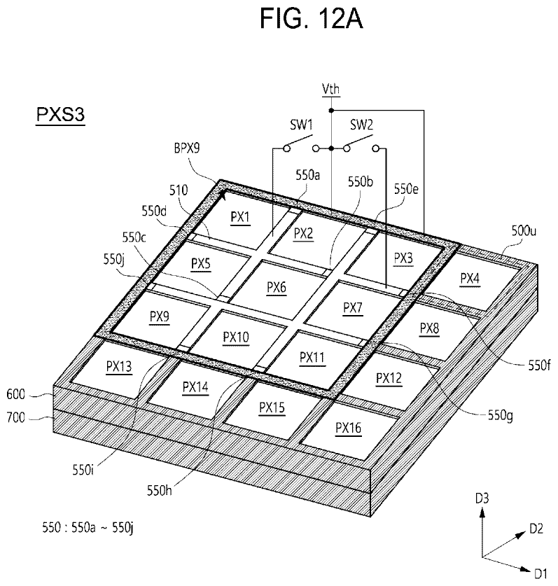

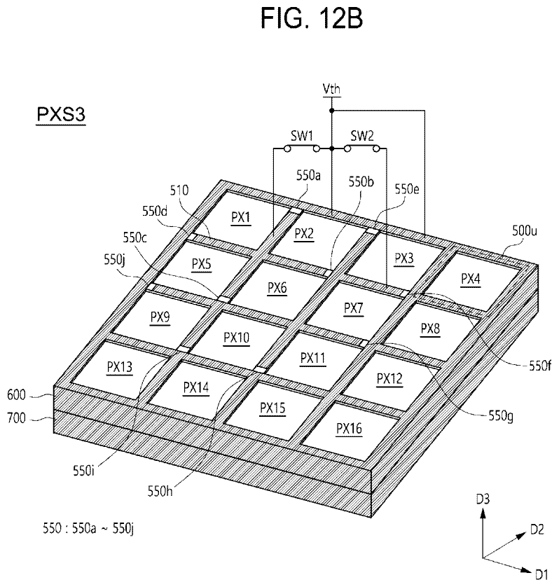

FIGS. 12A and 12B are perspective views illustrating a pixel array structure of an electronic device capable of changing the size of binning pixels based on example embodiments.

Referring to FIGS. 12A and 12B, when the pixel array structure PXS3 optionally includes a first binning pixel BPX4 (See FIGS. 11A and 11B) including the 2×2 unit pixels and the second binning pixel BPX9 including the 3×3 unit pixels to detect the light under certain conditions, the electronic device may include a first switch SW1 and a second switch SW2. Here, the first switch SW1 may correspond to the switch SW1 illustrated in FIGS. 11A and 11B. The configuration of the first to fourth isolation penetration portions 550a-550d and the first inner pixel isolation region 510 for delimiting the first binning pixel BPX4 may be the same as that illustrated in FIGS. 11A and 11B.

In order to change the first binning pixel BPX4 into the second binning pixel BPX9 including 3×3 unit pixels PX1, PX2, PX3, PX5, PX6, PX7, PX9, PX10 and PX11, the pixel array structure PXS3 may include fifth to tenth insulating penetration portions 550e-550j formed at a predetermined portion of the first and second pixel isolation regions 500x and 500y of the first binning pixel BPX4 and the adjacent unit pixels PX3, PX7, PX11, PX10 and PX9.

In example embodiments, the second binning pixel isolation layer 500b surrounding edges of the second binning pixel BPX9, the insulating penetration portions 550e-550j may be disposed between each of the first pixel isolation region 500x and the second pixel isolation region 500y in the second binning pixel isolation layer 500b that abuts a pure second binning pixel isolation layer 500b that does not overlap with the first binning pixel isolation layer 500b, thereby defining a second inner pixel isolation region 520.

The second inner pixel isolation area 520 may be connected to the threshold voltage supply terminal separately from the first inner pixel isolation area 510, via interconnect and a second switch SW2. The second switch SW2 may be electrically connected to a pixel array structure PXS3 or logic circuit structure LCS (see FIG. 8), similar to the first switch SW1.

For example, when the first switch SW1 is turned off and the second switch SW2 is turned on, a threshold voltage may be applied to the first binning pixel isolation layer 500a and the plurality of unit pixel isolation layers 500u, as described in FIG. 11A above. Accordingly, the first binning pixel BPX4 and the plurality of unit pixels may be confined in the pixel array structure PXS3.

On the other hand, when the first binning pixel BPX4 is changed into the second binning pixel BPX9, the first and second switches SW1 and SW2 may be turned off simultaneously. Then, no voltage may be applied to the first and second inner pixel isolation regions 510 and 520, and the first and second inner pixel isolation regions 510 and 520 may maintain their transparent state. The threshold voltage Vth may be applied to the second binning pixel isolation layer 500b and the other pixel isolation layers 500, so that the second binning pixel BPX9 comprising 3×3 pixels and a plurality of unit pixels may be defined.

When both the first and second switches SW1 and SW2 are turned on, the threshold voltage Vth may be applied to both the first and second inner pixel isolation regions 510 and 520, defining a unit pixel isolation layer 500u that partitions the plurality of unit pixels PX1-PX16 in the pixel array structure PXS3.

Thus, the pixel array structure PXS, PXS1-PXS3 may be defined with the binning pixels BPX4, BPX9 and unit pixels of various sizes, by the plurality of switches SW1 and SW2 and the plurality of insulating penetration portions 550a-550i.

The pixel isolation layer based on example embodiments may be formed of the material that penetrates the substrate and the interconnection layer including the pixel array structure to change the color in response to the voltage. As the transparency and color of the pixel isolation layer formed to penetrate the pixel array structure may change selectively based on the voltage, the optical crosstalk between the photo detecting elements as well as between the corresponding interconnection layers may be prevented. In particular, in the case of the Lidar device including the SPAD that generates the pixel current with only the single photon, the abnormal pixel current in off-pixels and the noise caused by the optical crosstalk in the interconnection layer may be prevented.

Furthermore, since the transparency of the pixel isolation layer may vary with the application of voltage, it is possible to form the binning pixels of different sizes by selectively applying voltage, while isolating the pixel isolation layer into distinct regions.

Although a number of illustrative embodiments have been described, it should be understood that modifications and enhancements to the disclosed embodiments and other embodiments can be devised based on what is described and/or illustrated in this patent document.

What is claimed is:

1. A pixel array structure comprising:
a substrate including a first surface and a second surface that is opposite to the first surface;
a plurality of photo detecting elements supported by the substrate;
an interconnection layer formed over the first surface of the substrate and including a plurality of interconnects connected to the plurality of photo detecting elements; and
a pixel isolation layer extending from the substrate to the interconnection layer and configured to isolate the plurality of photo detecting elements from each other,
wherein the pixel isolation layer exhibits a light transmission characteristic that varies depending on a voltage applied to the pixel isolation layer, wherein the light transmission characteristic includes at least one of transparency or color of the pixel isolation layer.

2. The pixel array structure of claim 1, wherein the pixel isolation layer comprises an electrochromic material that includes at least one of a metal oxide, an organic material, or a conductive polymer, wherein the metal oxide includes at least one of tungsten (W), iridium (Ir), molybdenum (Mo), nickel (Ni), or vanadium (V), wherein the organic material includes at least one of viologens or quinone, wherein the conductive polymer includes at least one of polythiophene, polyaniline (PANI), or polypyrrole.

3. The pixel array structure of claim 1, further comprising a grid pattern formed over the interconnection layer to be electrically connected to the pixel isolation layer, wherein a threshold voltage is provided to the pixel isolation layers via the grid pattern.

4. The pixel array structure of claim 1, wherein the photo detecting element comprises a single photon avalanche diode (SPAD) or an avalanche photo diode (APD), each of the SPAD and the APD including at least one p-n junction.

5. The pixel array structure of claim 1, wherein the pixel isolation layer comprises:
a first pixel isolation layer formed to penetrate the substrate; and
a second pixel isolation layer extending from the first pixel isolation layer to penetrate the interconnection layer.

6. The pixel array structure of claim 1, wherein the pixel isolation layer has a first state in response to the voltage applied to the pixel isolation layer that is lower than a threshold voltage, wherein the pixel isolation layer has a second state different from the first state in response to the voltage applied to the pixel isolation layer that is higher than or equal to the threshold voltage,
wherein the pixel isolation layer comprises:
a binning pixel isolation layer disposed on a periphery of at least two adjacent photo detecting elements among the plurality of photo detecting elements, wherein the at least two adjacent photo detecting elements operate as a binning pixel; and
a unit pixel isolation layer that individually defines each of the photo detecting elements except for the binning pixel,
wherein, in response to the voltage applied to the binning pixel isolation layer and the unit pixel isolation layer that is higher than or equal to the threshold voltage, the binning pixel isolation layer and the unit pixel isolation layer are converted to the second state.

7. The pixel array structure of claim 6, further comprising:
an inner pixel isolation region positioned between the at least two adjacent photo detecting elements surrounded by the binning pixel isolation layer; and
a plurality of insulating penetration portions positioned at intersections of the binning pixel isolation layer and the inner pixel isolation region,
wherein the plurality of insulating penetration portions is configured to place the inner pixel isolation region in an electrically floating state.

8. The pixel array structure of claim 7, wherein the binning pixel isolation layer, the insulating penetration portions, and the inner pixel isolation region have a same height.

9. An electronic device comprising:
a pixel array structure including: a plurality of photo detecting elements supported by a substrate; an interconnection layer including a plurality of interconnects positioned on a front side of the substrate; and a pixel isolation layer including a plurality of isolation regions extending from a back side of the substrate toward a front side of the interconnection layer and configured to isolate the plurality of photo detecting elements from each other; and
a logic circuit structure including a plurality of control logic circuits configured to provide a plurality of operating voltages to the plurality of interconnects in the interconnection layer,
wherein a transparency and a color of the pixel isolation layer change from a first state to a second state different from the first state based on a comparison between a threshold voltage and a voltage applied to the pixel isolation layer.

10. The electronic device of claim 9, wherein
the pixel isolation layer has the first state in response to the voltage applied to the pixel isolation layer that is lower than the threshold voltage,
the pixel isolation layer has the second state in response to the voltage applied to the pixel isolation layer that is higher than or equal to the threshold voltage, and
wherein the second state has a lower transparency than the first state, and the second state has a darker color than the first state.

11. The electronic device of claim 9, wherein the pixel isolation layer comprises an electrochromic material that includes at least one of a metal oxide, an organic material, or a conductive polymer, wherein the metal oxide includes at least one of tungsten (W), iridium (Ir), molybdenum (Mo), nickel (Ni), or vanadium (V), wherein the organic material includes at least one of viologens and quinone, wherein the conductive polymer includes at least one of polythiophene, polyaniline (PANI), or polypyrrole.

12. The electronic device of claim 10, further comprising:
a first bonding layer disposed over the interconnection layer of the pixel array structure, the first bonding layer including a plurality of first bonding pads electrically connected to the plurality of interconnects in the interconnection layer, and a first bonding insulating layer configured to insulate the plurality of first bonding pads from each other; and
a second bonding layer disposed over the logic circuit structure, the second bonding layer including a plurality of second bonding pads electrically connected to the plurality of logic circuits, and a second bonding insulating layer configured to insulate between the plurality of second bonding pads.

13. The electronic device of claim 12, wherein the pixel array structure and the logic circuit structure are stacked and the first bonding layer of the pixel array structure and the second bonding layer of the logic circuit structure are hybrid bonded.

14. The electronic device of claim 13, further comprising:
a conductive grid pattern disposed on the back side of the substrate of the pixel array structure, and electrically connected to the pixel isolation layer;
a color filter array layer disposed over the grid pattern; and
a plurality of micro-lenses disposed over the color filter array layer.

15. The electronic device of claim 14, wherein the pixel isolation layer receives the threshold voltage via the first bonding pad or the conductive grid pattern.

16. The electronic device of claim 9, wherein the pixel isolation layer further comprises:
a binning pixel isolation layer disposed on a periphery of at least two adjacent photo detecting elements among the plurality of photo detecting elements, wherein the at least two adjacent photo detecting elements operate as a binning pixel;
a unit pixel isolation layer that individually defines each of the photo detecting elements except for the binning pixel;
an inner pixel isolation region positioned between the at least two adjacent photo detecting elements surrounded by the binning pixel isolation layer; and
a plurality of insulating penetration portions positioned at intersections of the binning pixel isolation layer and the inner pixel isolation region,
wherein the plurality of insulating penetration portions is configured to place the inner pixel isolation region in an electrically floating state.

17. The electronic device of claim 16, wherein the pixel isolation layer further comprises at least one switch connected between the inner pixel isolation region and a threshold voltage terminal to selectively provide the threshold voltage to the inner pixel isolation region, thereby adjusting a size of the binning pixel.

18. The electronic device of claim 16, wherein the binning pixel isolation layer, the insulation penetration and the inner pixel isolation region have a same height.
